(19) United States
(12) Patent Application Publication
(10) Pub. No.: US 2010/0001314 A1
(43) Pub. Date: Jan. 7, 2010

(54) Bidirectional switch having control gate embedded in semiconductor substrate and semiconductor device

(75) Inventor: Hiroshi Yanagigawa, Shiga (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/458,201

(22) Filed: Jul. 2, 2009

(30) Foreign Application Priority Data
Jul. 4, 2008 (JP) 2008-175524

(51) Int. Cl. H01L 29/747

(52) U.S. Cl. 257/124; 257/E29.215

(57) ABSTRACT

A bidirectional switch includes a first switch and a second switch. The switch includes a well region of a first-conductivity-type formed on a semiconductor substrate, and serving as drains of the first switch and the second switch, a gate electrode of the first switch provided in a first trench formed in the well region through a first gate insulating film, a gate electrode of the second switch formed in a second trench formed in the well region so as to be spaced apart from the first trench with a second gate insulating film, a source region of the first switch formed on a side wall of the first trench, and on a surface of the well region via a first channel region of a second-conductivity-type, and a source region of the second switch formed on a side wall of the second trench, and on a surface of the well region via a second channel region of the second-conductivity-type. The well region is formed in a region between the first trench and the second trench.

### INCORPORATION BY REFERENCE

This application is based upon and claims the benefit of priority from Japanese Patent Application No. 2008-175524 which was filed on Jul. 4, 2008, the disclosure of which is incorporated herein in its entirety by reference.

### BACKGROUND OF THE INVENTION

1. Field of the Invention

The present invention relates to a bidirectional switch and a semiconductor device, particularly to a bidirectional switch capable of controlling switching in each of two directions individually, and to a semiconductor device.

2. Description of Related Art

A power unit, for example, for a lithium ion battery performs controls for both charging and discharging of the lithium ion battery, in order to avoid excessive charging and discharging of the lithium ion battery. To this end, required is a semiconductor device provided with a bidirectional switch which allows electric currents to flow in two directions. For more accurate charging and discharging, the semiconductor device provided with the bidirectional switch is further required to control switching in each of two directions individually.

Such a semiconductor device provided with a bidirectional switch uses a bidirectional element in which unidirectional semiconductor elements are anti-serially connected to each other. Each of these unidirectional semiconductor elements, however, has drain resistance. For this reason, when being anti-serially connected, the unidirectional semiconductor elements have doubled drain resistance, and thereby inevitably have high on-resistance. A bidirectional switch for preventing this problem is disclosed in Patent Document 1, for example.

FIG. 5 shows configuration views of a semiconductor device disclosed in Patent Document (Japanese Patent Application Publication No. 2004-274039). FIG. 5A is a plan view of a principal part, FIG. 5B is an enlarged view of a VB part shown in FIG. 5A, and FIG. 5C is a cross-sectional view of a principal part shown in FIG. 5A, which is taken along a VC-VC line.

In the semiconductor device disclosed in Patent Document shown in FIG. 5, an n-well region 32 is formed on a p-semiconductor substrate 31, trenches 33 are formed in the n-well region 32, an n-extended drain region 34 is formed under a bottom surface 33a of each of the trenches, and a p-offset region 35 is formed on a surface layer of the n-well region 32.

A gate insulating film 36 is formed on each inner wall of the trench 33, and a gate electrode 37 is formed on each side wall 33b of the trench with the gate insulating film 36 interposed in between. A first n-source region 39 or a second n-source region 310 is selectively formed on a surface of the p-offset region 35 between each two adjacent trenches 33, so as to be in contact with the trenches 33. The first n-source regions 39 and the second n-source regions 310 are alternately formed with the trenches 33 interposed in between. An interlayer insulating film 38 is filled in a portion above the gate electrodes 37 and inside the trenches 33, so that the trenches 33 are evened out. After the interlayer insulating film 38a is formed on an entire surface, contact holes are opened in the interlayer insulating film 38a. After that, first source electrodes 311 and second source electrodes 312 are respectively formed on the first n-source regions 39 and the second n-source regions 310. The first source electrodes 311 are connected to each other through a first source wiring 313, and the second source electrodes 312 are connected to each other through a second source wiring 314. Each of the gate electrodes 37 is connected to an unillustrated gate pad through a gate wiring.

As described above, the n-well region 32 is used as a common drain for the two MOS switches in Patent Document. This lowers drain resistance compared to that occurring in the semiconductor device in which the unidirectional semiconductor elements are anti-serially connected to each other so as to serve as a bidirectional element. In addition, in Patent Document, the n-extended drain regions 34 are formed respectively under the bottom portions of the trenches 33, thereby increasing the breakdown voltage.

### SUMMARY

Patent Document, however, requires that the n-extended drain region 34 be provided under the bottom portion of the trench 33. For this reason, the trenches 33 each having a certain width need to be formed, and the width of the trench 33 cannot be reduced. Forming each of the trenches 33 with a large width makes it difficult to obtain a flat bottom portion of the trench 33, thereby deteriorating the quality of the gate insulating films 36 formed in the trench 33. In addition, after the gate electrodes 37 are formed in the trench 33, the trench 33 is filled with the interlayer insulating film 38 which has low thermal conductivity, leading to deterioration in heat dissipation properties near a current path. These cause problems of making a threshold voltage Vt unstable and on-resistance high.

Moreover, in Patent Document, the two separate gate electrodes 37 need to be formed in each of the trenches 33, which makes a process complicated.

A bidirectional switch according to an exemplary aspect of the present invention includes a first switch and a second switch. The switch includes a well region of a first-conductivity-type formed on a semiconductor substrate, and serving as drains of the first switch and the second switch, a gate electrode of the first switch provided in a first trench formed in the well region through a first gate insulating film, a gate electrode of the second switch formed in a second trench formed in the well region so as to be spaced apart from the first trench with a second gate insulating film, a source region of the first switch formed on a side wall of the first trench, and on a surface of the well region via a first channel region of a second-conductivity-type, and a source region of the second switch formed on a side wall of the second trench, and on a surface of the well region via a second channel region of the second-conductivity-type. The well region is formed in a region between the first trench and the second trench.

The configuration described above allows a region between a trench gate of the first switch and a trench gate of the second switch to be formed by a well region which also serves as a drain, so that the heat dissipation properties near a current path are improved. Moreover, the configuration eliminates the need for forming trenches large in width, and thus trenches each having a flat bottom portion can be formed. Accordingly, the quality of the gate insulating films is improved.

The present invention can provide a bidirectional switch element with reduced on-resistance and a constant threshold voltage, and a semiconductor device.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a plan view of a bidirectional switch according to a first exemplary embodiment;

FIG. 2 is a cross-sectional view of the bidirectional switch according to the first exemplary embodiment;

FIG. 3 is a circuit diagram of a semiconductor device according to the first exemplary embodiment;

FIG. 4 is a cross-sectional view of a bidirectional switch according to a second exemplary embodiment; and

FIG. 5 shows configuration views of a semiconductor device of a related art.

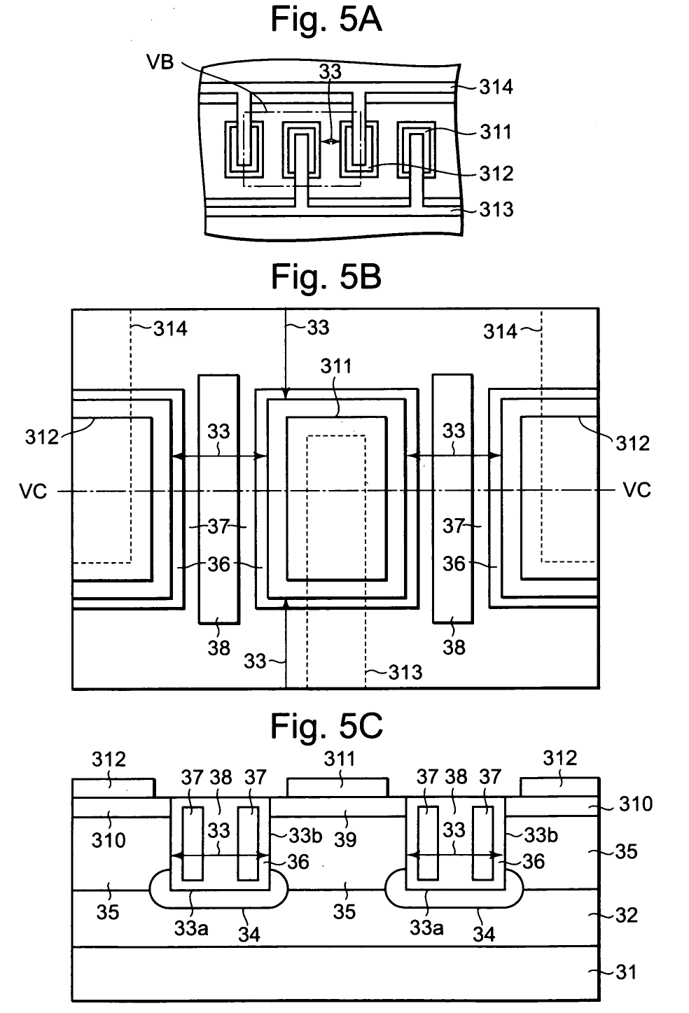

### DETAILED DESCRIPTION OF THE EXEMPLARY EMBODIMENTS

### First Exemplary Embodiment

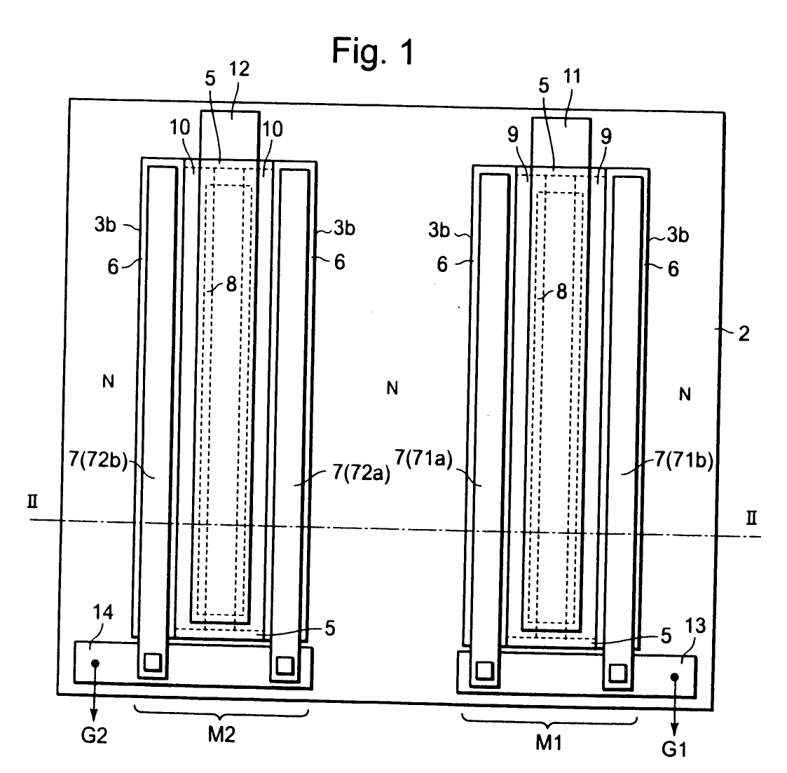

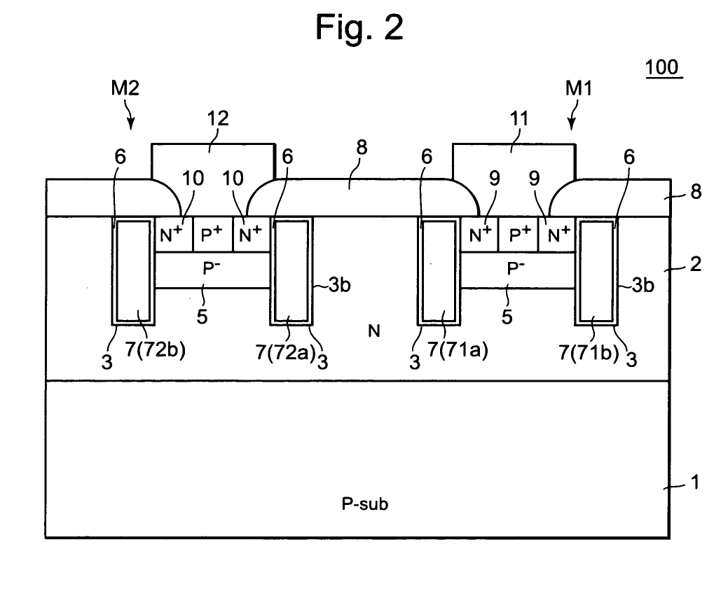

FIG. 1 is a plan view of the bidirectional switch 100 according to a first exemplary embodiment. FIG. 2 is a cross-sectional view of the bidirectional switch 100 according to the first exemplary embodiment. FIG. 2 shows a cross-sectional view taken along II-II line of FIG. 1. The bidirectional switch 100 is a bidirectional semiconductor element provided with a first MOS switch M1 and a second MOS switch M2, as shown in FIG. 1 and FIG. 2.

In FIG. 1 and FIG. 2, an N-well region 2 having an impurity concentration of a 30 predetermined level is formed on a P-semiconductor substrate 1. Trenches 3 are formed in the N-well region 2 at predetermined intervals. In the exemplary embodiment, four trenches 3 are formed. Gate insulating films (gate oxide films) 6 are respectively formed on side walls 3b of the trenches 3.

Inside each of the trenches 3, a gate electrode 7 is formed with the gate insulating film interposed in between. In other words, the trenches 3 are each provided with a single gate electrode 7. In FIG. 1 and FIG. 2, first gate electrodes 71a and 71b, serving as gate electrodes 71 of the first MOS switch M1, are respectively provided in the two trenches 3 on the right side. Here, the first gate electrode 71a is designed to be provided on a side close to the second MOS switch M2, and the first gate electrode 71b is designed to be provided on a side opposite to the side close to the second MOS switch M2. Second gate electrodes 72a and 72b, serving as gate electrodes 72 of the second MOS switch M2, are respectively provided in the two trenches 3 on the left side of the drawings. Here, the second gate electrode 72a is designed to be provided on a side close to the first MOS switch M1, and the second gate electrode 72b is designed to be provided on a side opposite to the side close to the first MOS switch M1.

In this manner, the trenches 3 are provided respectively for the gate electrodes 7. Accordingly, a region between two adjacent trenches of the first MOS switch M1 and the second MOS switch M2, that is, a region between the trench 3 provided with the first gate electrode 71a and the trench 3 provided with the second gate electrode 72a, can be the N-well region 2.

In each of the first MOS switch M1 and the second MOS switch M2, a P-offset region 5 is selectively formed on a surface layer of the N-well region 2 between the trench 3 provided with one of the gate electrodes 7 and the other trench 3 provided with the other gate electrode 7. In other words, the P-offset region 5 is selectively formed on a surface layer of the N-well region 2 in a region between the trench 3 provided with the first gate electrode 71a and the trench 3 provided with the first gate electrode 71b. Similarly, the P-offset region 5 is selectively formed on a surface layer of the N-well region 2 in a region between the trench 3 provided with the second gate electrode 72b and the trench 3 provided with the second gate electrode 72a. The P-offset region 5 is a channel region in which a channel is formed when a voltage is applied to the gate electrodes 7, as will be described later.

On a surface of each of the P-offset regions 5, either N+ source regions 9 or second N+ source regions 10 are further formed so as to be in contact with the corresponding trenches 3, respectively. The first N+ source regions 9 are provided in the first MOS switch M1, and formed so as to be in contact respectively with the trenches 3 provided with the first gate electrodes 71a and 71b. On the other hand, the second N+ source regions 10 are provided in the second MOS switch M2, and formed so as to be in contact respectively with the trenches 3 provided with the second gate electrodes 72a and 72b. The first N+ source regions 9 and the second N+ source regions 10 each have impurity concentration higher than that of the N-well region 2.

Over these regions, an interlayer insulating film 8 is formed. The interlayer insulating film 8 has contact holes opened above the first N+ source regions 9 and the second N+ source regions 10. On the interlayer insulating film 8, a first source wiring 11 of the first MOS switch M1 and a second source wiring 12 of the second MOS switch M2 are formed. The first source wiring 11 is provided so as to be connected to the first N+ source region 9 through one of the contact holes. Similarly, the second source wiring 12 is provided so as to be connected to the second N+ source region 10 through the other contact hole.

The first gate electrodes 71a and 71b are connected to a first gate wiring 13, as shown in FIG. 1. Meanwhile, the second gate electrodes 72a and 72b are connected to a second gate wiring 14.

In this manner, in the exemplary embodiment, the trenches 3 are provided respectively for the gate electrodes 7, and the region between the trench 3 provided with the first gate electrode 71a and the trench 3 provided with the second gate electrode 72a is designed to be the N-well region 2.

Accordingly, the region between the trench 3 provided with the first gate electrode 71a and the trench 3 provided with the second gate electrode 72a is the N-well region 2 having thermal conductivity higher than that of the interlayer insulating film 38 of Patent Document. For example, suppose a silicon oxide film (thermal conductivity of 0.014 W/cm K) is employed as the interlayer insulating film 38 of Patent Document. The thermal conductivity of silicon (thermal conductivity of 1.5 W/cm K) serving as the N-well region 2 is 100 or more times higher than that of the silicon oxide film. Thus, the heat dissipation properties near the current path can be improved.

In addition, the width of each of the trenches 3 is made narrower than that of each of the trenches 33 of Patent Document. This makes it easy to obtain the trench 3 with a flat bottom portion, and thus the quality of the gate insulating film 6 formed in the trench 3 is improved. Furthermore, the gate electrodes 7 do not need to be formed separately in a single trench 3, thereby simplifying the process. Specifically, the N-well region 2 is formed on the P-semiconductor substrate 1, and the trenches 3 are formed in the N-well region 2. Then, after the gate insulating films 6 are respectively formed on the trenches 3, polysilicon to serve as the gate electrodes 7 is grown on an entire surface of these thus formed, and the polysilicon is etched back thereafter. Only through this procedure, the gate electrodes 7 can be formed. Then, the P-offset regions 5 are selectively formed on a surface layer of the N-well region 2, and the first N+ source regions 9 and the second N+ source regions 10 are selectively formed on the surfaces of the P-offset regions 5. After the interlayer insulating film 8 is formed over these thus formed, the first source wiring 11 and the second source wiring 12 are formed which are to be connected to the first N+ source regions 9 and the second N+ source regions 10 through the contact holes of the interlayer insulating films 8.

In the bidirectional switch 100 having such a configuration, the N-well region 2 functions both as a drain of the first MOS switch M1 and as a drain of the second MOS switch M2. When a voltage is applied to the gate electrodes 71, a channel is formed on each side surface of the P-offset region 5 sandwiched between each of the first N+ source regions 9, and the N-well region 2. When a voltage is applied to the gate electrodes 72, a channel is formed on each side surface of the P-offset region 5 sandwiched between each of the second N+ source regions 10, and the N-well region 2.

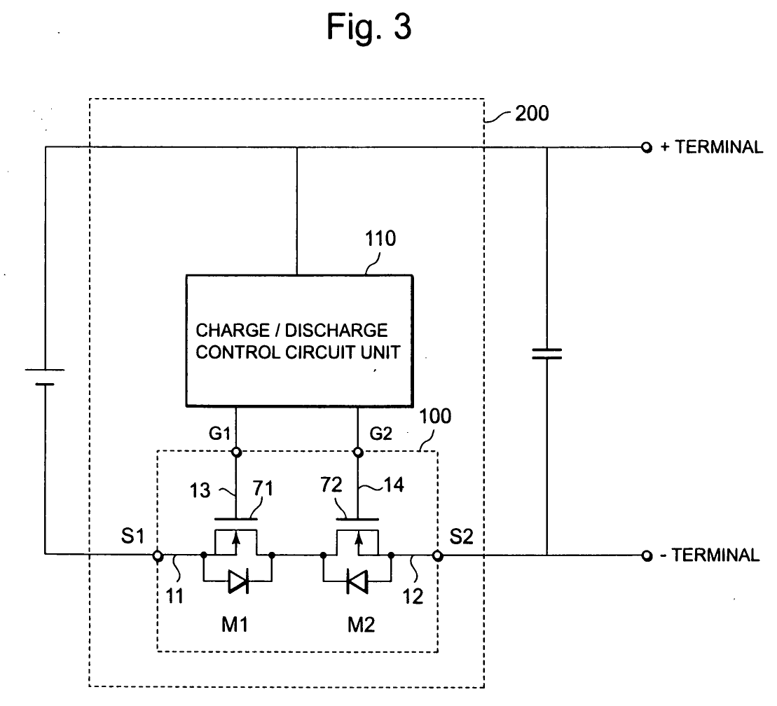

Next, a description is given of an operation of a semiconductor device 200 including the bidirectional switch 100 according to the exemplary embodiment, with reference to FIG. 3. FIG. 3 is a circuit diagram of the semiconductor device 200 according to the first exemplary embodiment. In FIG. 3, a case where the semiconductor device 200 is mounted on a lithium ion battery for a mobile phone is shown as an example.

As shown in FIG. 3, the semiconductor device 200 includes a bidirectional switch 100 and a charge/discharge control circuit unit 110. The charge/discharge control circuit unit 110 controls the bidirectional switch 100. The charge/discharge control circuit unit 110 is connected to the first gate terminal G1 and the second gate terminal G2 of the bidirectional switch 100. The first gate terminal G1 is electrically connected to a gate (gate electrodes 71) of the first MOS switch M1 through the first gate wiring 13. The second gate terminal G2 is electrically connected to a gate (gate electrodes 72) of the second MOS switch M2 through the second gate wiring 14.

In the bidirectional switch 100, the drain of the first MOS switch M1 and the drain of the second MOS switch M2 are formed in common as described above. A source of the first MOS switch M1 is electrically connected to a first source terminal S1 through the first source wiring 11. A source of the second MOS switch M2 is electrically connected to a second source terminal S2 through the second source wiring 12. The bidirectional switch 100 is connected so that the first source terminal S1 would be connected to a lithium ion battery 210 while the second source terminal S2 would be connected to a load 220.

In the above-described semiconductor device 200, the first MOS switch M1 functions as a discharge MOSFET, and the second MOS switch M2 functions as a charge MOSFET. When the charge/discharge control circuit unit 110 applies a high voltage H to the first gate terminal G1 and the second gate terminal G2, the first MOS switch M1 and the second MOS switch M2 are turned on, so that the bidirectional switch 100 goes into a conducting state. Accordingly, a charging current flows to the lithium ion battery 210, and a discharging current flows from the lithium ion battery 210 to the load 220. In other words, the semiconductor device 200 can carry out both charging and discharging of the lithium ion battery 210.

In contrast to this case, when the charge/discharge control circuit unit 110 applies a low voltage L to the first gate terminal G1 and the second gate terminal G2, the first MOS switch M1 and the second MOS switch M2 are turned off, so that the bidirectional switch 100 goes into an open state. Accordingly, the semiconductor device 200 can stop both charging and discharging of the lithium ion battery 210.

On the other hand, when the charge/discharge control circuit unit 110 applies a high voltage H to the first gate terminal G1 and a low voltage L to the second gate terminal G2, the first MOS switch M1 is turned on whereas the second MOS switch M2 is turned off. Accordingly, a charging current stops flowing, while a discharging current flows to the load 220 through a parasitic diode of the second MOS switch M2. In other words, the semiconductor device 200 can stop charging of the lithium ion battery 210 and only carry out discharging of the lithium ion battery 210.

By contrast, when the charge/discharge control circuit unit 110 applies a low voltage L to the first gate terminal G1 and a high voltage H to the second gate terminal G2, the first MOS switch M1 is turned off, whereas the second MOS switch M2 is turned on. Accordingly, a discharging current stops flowing, while a charging current flows to the lithium ion battery 210 through a parasitic diode of the first MOS switch M1. In other words, the semiconductor device 200 can stop discharging of the lithium ion battery 210 and only carry out charging of the lithium ion battery 210.

Controlling gates of the semiconductor device 200 in this manner makes it possible to control on and off for the current flows, thereby controlling switching in each of two directions individually.

Note that currents flowing between the first MOS switch M1 and the second MOS switch M2 flow below the gate electrodes 7 in lateral directions in the cross-sectional view of FIG. 2, and do not flow into a region between the first gate electrode 71a and the second gate electrode 72a. Hence, from a view point of a breakdown voltage, the region does not need to be formed of an interlayer insulating film 38, and may be formed of the N-well region 2. In the exemplary embodiment, the breakdown voltage is ensured by increasing a distance between the first gate electrode 71a and the second gate electrode 72a. In other words, the breakdown voltage between adjacent elements can be improved without increasing the width of each trench. For this reason, the trench does not need to be increased in width for the improvement in the breakdown voltage. Accordingly, a desired breakdown voltage can be ensured by adjusting a film thickness of each of the gate insulating films 6, a concentration of the N-well region 2, and a distance between the first gate electrode 71a and the second gate electrode 72a. For example, when being mounted on a lithium ion battery for a mobile phone, the bidirectional switch 100 is required to have a breakdown voltage of 30V or more, for the purpose of charging using a battery of a vehicle, or for other purposes.

As described above, in the exemplary embodiment, the trenches 3 are provided for the gate electrodes 7, respectively, and the region between the trench 3 provided with the first gate electrode 71a and the trench 3 provided with the second gate electrode 72a is designed to be the N-well region 2. In other words, the region between the trench gate of the first MOS switch M1 and the trench gate of the second MOS switch M2 are formed of an N-well region 2 which also serves as a drain, so that the heat dissipation properties near the current path can be increased. Moreover, the configuration eliminates the need for forming the trenches 3 large in width, and thus the trenches 3 each having a flat bottom portion can be formed. Accordingly, the quality of the gate insulating films 6 increases. Accordingly, a threshold voltage Vt can be made constant, and a reduction in on-resistance can be achieved.

### Second Exemplary Embodiment

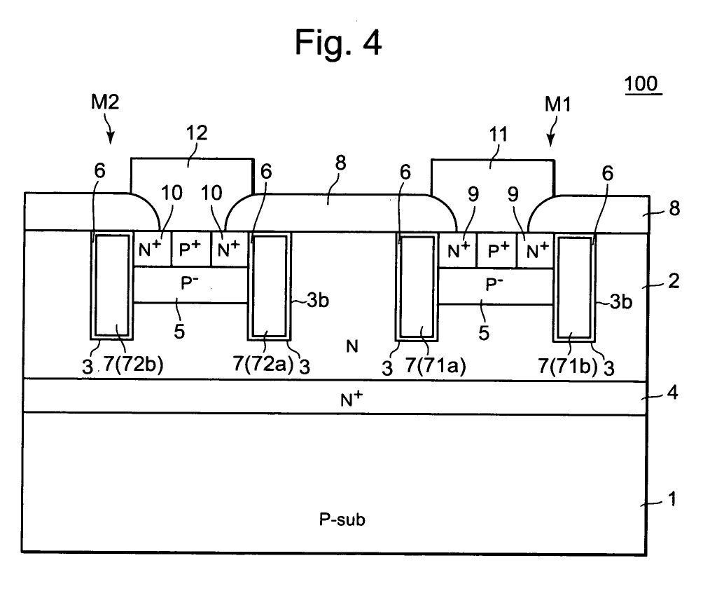

FIG. 4 is a cross-sectional view of the bidirectional switch 100 according to a second exemplary embodiment. FIG. 4 shows, as in FIG. 2, a cross-sectional view taken along II-II line of FIG. 1.

As shown in FIG. 4, an N+ embedded diffusion layer 4 is further formed between a P-semiconductor substrate 1 and an N-well region 2. The N+ embedded diffusion layer 4 has an impurity concentration higher than that of the N-well region 2. The configuration other than this point is the same as that of the first exemplary embodiment, thereby omitting the description thereof. This configuration improves separation between elements from each other, in addition to the same effects as those of the first exemplary embodiment.

The above description is given of the exemplary embodiments of the present invention, but the present invention is not limited to the above exemplary embodiments. In addition, those skilled in the art may easily modify, add, or replace each component in the above exemplary embodiments within the scope of the present invention.

Further, it is noted that Applicant's intent is to encompass equivalents of all claim elements, even if amended later during prosecution.

What is claimed is:

1. A bidirectional switch including a first switch and a second switch, comprising:
a well region of a first-conductivity-type formed on a semiconductor substrate, and serving as a drain of the first switch and as a drain of the second switch;
a first gate electrode of the first switch provided in a first trench formed in the well region through a first gate insulating film;
a second gate electrode of the second switch formed in a second trench formed in the well region through a second gate insulating film, the second trench being spaced apart from the first trench;
a first source region of the first switch formed on a surface of the well region exposed by a side wall of the first trench via a first channel region of a second-conductivity-type; and
a second source region of the second switch formed on a surface of the well region exposed by a side wall of the second trench via a second channel region of the second-conductivity-type,
wherein the well region is formed in a region between the first trench and the second trench.

2. The bidirectional switch according to claim 1,
wherein the first trench is provided corresponding to the first gate electrode of the first switch, and
wherein the second trench is provided corresponding to the second gate electrode of the second switch.

3. The bidirectional switch according to claim 1, further comprising:
a diffusion layer provided between the semiconductor substrate and the well region, the diffusion layer having a first-conductivity-type impurity concentration higher than that of the well region.

4. The bidirectional switch according to claim 1, wherein the first source region of the first switch and the second source region of the second switch each have a first-conductivity-type impurity concentration higher than that of the well region.

5. A semiconductor device, comprising:
the bidirectional switch according to claim 1; and
a control circuit unit controlling the bidirectional switch.

6. The semiconductor device according to claim 5,
wherein the control circuit unit is electrically connected to each of the first gate electrode of the first switch and the second gate electrode of the second switch.

7. A semiconductor device, comprising:
a well region of a first-conductivity-type including a first trench, a second trench, a third trench and a fourth trench in that order;
a first gate electrode having a first gate portion formed in the first trench and a second gate portion formed in the second trench;
a second gate electrode having a third gate portion formed in the third trench and a fourth gate portion formed in the fourth trench;
a first region of a second-conductivity-type formed between the first and second gate portions, the first region having a lower surface contacting the well region, the lower surface of the first region being positioned higher than a bottom surface of the first and second gate portions;
a second region of the second-conductivity-type formed between the third and fourth gate portions, the second region having a lower surface contacting the well region, the lower surface of the second region being positioned higher than a bottom surface of the third and fourth gate portions;
a third region of the first-conductivity-type formed on the first region;
a fourth region of the first-conductivity-type formed on the second region;
a first source region including a first source portion formed on the first region and placed between the third region and the first gate portion, and a second source portion formed on the first region and placed between the third region and the second gate portion;
a second source region including a third source portion formed on the first region and placed between the fourth region and the third gate portion, and a fourth source portion formed on the first region and placed between the fourth region and the fourth gate portion;
a first source electrode which contacts the first and second source portions and the third region; and
a second source electrode which contacts the third and fourth source portions and the fourth region.

8. The semiconductor device as claimed in claim 7, further comprising:
a layer of the first-conductivity-type formed between the well region and a semiconductor substrate, an impurity concentration of the layer being an impurity concentration of the well region.
